(19) United States
(12) Patent Application Publication
(10) Pub. No.: US 2026/0341929 A1
(43) Pub. Date: Oct. 29, 2026

(54) PROTECTION CIRCUIT MODULE AND BATTERY ASSEMBLY INCLUDING THE SAME

(71) Applicant: SAMSUNG SDI CO., LTD., Yongin-si (KR)

(72) Inventors: Harim LEE, Yongin-si (KR); Jiyun CHOI, Yongin-si (KR); Minje JEONG, Yongin-si (KR)

(21) Appl. No.: 19/329,828

(22) Filed: Sep. 16, 2025

(30) Foreign Application Priority Data
Apr. 23, 2025 (KR) 10-2025-0053384

(51) Int. Cl. H01M 50/574; H05K 1/14

(52) U.S. Cl. CPC H01M 50/574; H05K 1/14

(57) ABSTRACT

A protection circuit module, including a protection circuit board extending in a first direction, and a flexible circuit board electrically connected to the protection circuit board, wherein the protection circuit board includes a first binding portion overlapping with the flexible circuit board in a second direction perpendicular to the first direction, the first binding portion of the protection circuit board is coupled to the flexible circuit board, and a thickness of the first binding portion is less than a thickness of an area other than the first binding portion in the protection circuit board.

### CROSS-REFERENCE TO RELATED APPLICATION

This application claims priority under 35 U.S.C. §119 to Korean Patent Application No. 10-2025-0053384, filed in the Korean Intellectual Property Office on Apr. 23, 2025, the entire contents of which are hereby incorporated by reference.

### BACKGROUND

### 1. Field

The present disclosure relates to a protection circuit module and a battery assembly including the protection circuit module.

### 2. Description Of The Related Art

Unlike primary batteries that are not designed to be (re)charged, secondary (or rechargeable) batteries are batteries that are designed to be discharged and recharged. Low-capacity secondary batteries are used in portable, small electronic devices, such as smart phones, feature phones, notebook computers, digital cameras, and camcorders, while large-capacity secondary batteries are widely used as power sources for driving motors in hybrid vehicles and electric vehicles and for storing power (e.g., home and/or utility scale power storage). A secondary battery generally includes an electrode assembly composed of a positive electrode and a negative electrode, a case accommodating the same, and electrode terminals connected to the electrode assembly.

A secondary battery may be provided with a protection circuit module (PCM) for protecting the battery from overcharge, overdischarge, or overcurrent. The protection circuit module may prevent ignition or explosion of the battery by blocking current flow when the internal temperature or voltage of the battery rises.

The above information disclosed in this Background section is for enhancement of understanding of the background of the present disclosure, and therefore, it may contain information that does not constitute related (or prior) art.

### SUMMARY

Embodiments include a protection circuit module, including a protection circuit board extending in a first direction, and a flexible circuit board electrically connected to the protection circuit board, wherein the protection circuit board includes a first binding portion overlapping with the flexible circuit board in a second direction perpendicular to the first direction, the first binding portion of the protection circuit board is coupled to the flexible circuit board, and a thickness of the first binding portion is less than a thickness of an area other than the first binding portion in the protection circuit board.

The flexible circuit board may include a second binding portion overlapping with the protection circuit board in a second direction perpendicular to the first direction.

The protection circuit board may include a first protective layer, a base layer, and a second protective layer that are sequentially stacked, and at least a portion of the first protective layer is removed in the first binding portion.

Each of the first protective layer and the second protective layer may include a first insulating layer, a first copper layer, a second copper layer, and a second insulating layer.

The flexible circuit board may include a first flexible protective layer, a flexible base layer, and a second flexible protective layer that are sequentially stacked, and at least a portion of the first flexible protective layer is removed in the second binding portion.

The first flexible protective layer may include a coverlay layer.

The first binding portion may be at one end of the protection circuit board.

The second binding portion may be at one end of the flexible circuit board.

The protection circuit may further include an insulating resin between the protection circuit board and the flexible circuit board.

The insulating resin may include a first insulating portion between the protection circuit board and the flexible circuit board in the second direction, and a second insulating portion between the protection circuit board and the flexible circuit board in the first direction.

The flexible circuit board includes at least one connection member on the second binding portion, the flexible circuit board being electrically connected to the protection circuit board.

The at least one connection member may be connected to the flexible base layer of the second binding portion and the base layer of the first binding portion.

The base layer may include a plurality of second copper layers and an insulating layer between the plurality of second copper layers.

The flexible base layer may include a plurality of first copper layers, and a flexible copper clad laminate between the plurality of first copper layers.

The flexible circuit board may include at least one connection member on the flexible base layer, the flexible circuit board being electrically connected to the flexible base layer and the base layer.

Embodiments include a protection circuit module, including a protection circuit board extending in a first direction, a flexible circuit board overlapping with the protection circuit board in a second direction perpendicular to the first direction, and a connection member between the protection circuit board and the flexible circuit board, wherein the protection circuit board may include a base layer, a first protective layer on a lower surface of the base layer, the first protective layer not overlapping with the flexible circuit board in the second direction, and a second protective layer on an upper surface of the base layer, wherein the flexible circuit board may include a flexible base layer, a first flexible protective layer on an upper surface of the flexible base layer, the first flexible protective layer not overlapping with the protection circuit board in the second direction, and a second flexible protective layer on a lower surface of the flexible base layer, and wherein the connection member electrically connects the lower surface of the base layer with the upper surface of the flexible base layer.

A lower surface of the protection circuit board may include a first stepped surface with the first protective layer, and an upper surface of the flexible circuit board corresponds to the first stepped surface, the upper surface of the flexible circuit board including a second stepped surface with the first flexible protective layer.

The protection circuit module may further include an insulating resin between the protection circuit board and the flexible circuit board, wherein the insulating resin may include a first insulating portion between the base layer and the flexible base layer in the second direction, and a second insulating portion between the first protective layer and the flexible circuit board in the first direction.

Embodiments include a battery assembly, including a battery cell including an electrode tab, and a protection circuit module electrically connected to the electrode tab, wherein the protection circuit module may include a protection circuit board electrically connected to the battery cell, the protection circuit board extending in a first direction, and a flexible circuit board electrically connected to the protection circuit board, wherein the protection circuit board includes a first binding portion overlapping with the flexible circuit board in a second direction perpendicular to the first direction, the first binding portion of the protection circuit board is coupled to the flexible circuit board, and a thickness of the first binding portion is less than a thickness of an area other than the first binding portion in the protection circuit board.

The flexible circuit board may include a second binding portion overlapping with the protection circuit board in a second direction perpendicular to the first direction, the second binding portion of the flexible circuit board is coupled to the protection circuit board, and a thickness of the second binding portion is less than a thickness of an area other than the second binding portion in the flexible circuit board.

However, aspects and features of the present disclosure are not limited to those described above, and other aspects and features not mentioned will be clearly understood by a person skilled in the art from the detailed description, described below.

### BRIEF DESCRIPTION OF DRAWINGS

The following drawings attached to this specification illustrate embodiments of the present disclosure, and further describe aspects and features of the present disclosure together with the detailed description of the present disclosure. Thus, the present disclosure should not be construed as being limited to the drawings.

Features will become apparent to those of skill in the art by describing in detail exemplary embodiments with reference to the attached drawings, in which:

FIG. 1 is an exploded perspective view illustrating a battery assembly 100 according to an embodiment of the present disclosure;

FIG. 2 is a plan view illustrating a battery assembly 100 according to an embodiment of the present disclosure;

FIG. 3 illustrates a protection circuit module according to an embodiment of the present disclosure;

FIG. 4 illustrates an example in which a protection circuit board and a flexible circuit board are coupled according to an embodiment of the present disclosure;

FIG. 5 illustrates an example in which a protection circuit board and a flexible circuit board are coupled according to an embodiment of the present disclosure;

FIG. 6 illustrates an example of a stacked structure constituting a protection circuit board according to an embodiment of the present disclosure;

FIG. 7 illustrates an example of layers constituting a flexible circuit board according to an embodiment of the present disclosure;

FIG. 8 illustrates an exemplary insulating resin and connection member in a coupling structure between a protection circuit board and a flexible circuit board according to an embodiment of the present disclosure; and

FIG. 9 illustrates an example in which a protection circuit board and a flexible circuit board are coupled according to an embodiment of the present disclosure.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

Hereinafter, embodiments of the present disclosure will be described, in detail, with reference to the accompanying drawings. The terms or words used in the present specification and claims are not to be limitedly interpreted as general or dictionary meanings and should be interpreted as meanings and concepts that are consistent with the technical idea of the present disclosure on the basis of the principle that an inventor can be his/her own lexicographer to appropriately define concepts of terms to describe his/her invention in the best way. Therefore, the embodiments described in this specification and the configurations shown in the drawings are only some of the embodiments of the present disclosure and do not represent all of the technical spirit, aspects, and features of the present disclosure. Accordingly, it should be understood that there may be various equivalents and modifications that can replace or modify the embodiments described herein at the time of filing this application.

Also, it will be further understood that the terms "includes," "including," “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Also, in the figures, dimensions of the various elements, layers, etc. may be exaggerated for clarity of illustration. The same reference numerals designate the same elements.

References to two compared elements, features, etc. as being “the same” may mean that they are “substantially the same”. Thus, the phrase “substantially the same” may include a case having a deviation that is considered low in the art, for example, a deviation of 5% or less. In addition, when a certain parameter is referred to as being uniform in a given region, it may mean that it is uniform in terms of an average.

It will be understood that, although the terms first, second, etc. may be used herein to describe various elements, these elements should not be limited by these terms. These terms are only used to distinguish one element from another element. Thus, a first element could be termed a second element unless the context clearly indicates otherwise.

Throughout the specification, unless otherwise stated, each element may be singular or plural.

Arranging an arbitrary element “above (or below)” or “on (under)” another element may mean that the arbitrary element may be disposed in contact with the upper (or lower) surface of the element, and another element may also be interposed between the element and the arbitrary element disposed on (or under) the element.

In addition, it will be understood that when a component is referred to as being "linked," "coupled," or "connected" to another component, the elements may be directly “coupled,” “linked” or "connected" to each other, or another component may be "interposed" between the components". It will also be understood that when an element is referred to as being “electrically coupled” to another element, it may be directly coupled to the other element or intervening elements may be present.

Throughout the specification, when "A and/or B" is stated, it means A, B or A and B, unless otherwise stated. That is, “and/or” includes any or all combinations of a plurality of items enumerated. When "C to D" is stated, it means C or more and D or less, unless otherwise specified.

The terminology used herein is for the purpose of describing embodiments of the present disclosure and is not intended to be limiting of the present disclosure.

A secondary battery may be classified into a can type and a pouch type according to a shape of a case, and the can type may be classified into a prismatic type and a cylindrical type. When a secondary battery is of a can type, a battery cell may include a can having an approximately rectangular parallelepiped or cylindrical shape, and a cap assembly coupled to an opening of the can to seal the can. The battery cell may include a battery case, an electrode assembly accommodated in the battery case, and an electrolyte.

When a case is of a can type, a battery cell and a protection circuit module are electrically connected through a conductor referred to as a lead or a lead plate. For example, a lead plate may be connected to the battery cell by a method such as welding while being attached to the protection circuit module. In the present disclosure, a configuration in which a protection circuit module is coupled to a battery cell as described above may be referred to as a battery assembly.

In addition, as a structure for covering a space between a battery cell and a protection circuit module and a surface of the protection circuit module, a molding by a molding resin or a form using a separate exterior case may be used. A tab connection portion of the protection circuit module is connected to a lead plate for electrical connection to a battery cell, and an external connection terminal may be connected to an external electronic device to form an electrical path during charging and discharging.

The secondary battery formed as described above is referred to as a battery cell, and the battery cell may be electrically connected to a protection circuit module to form a battery assembly. In the present disclosure, a case in which the battery cell is a pouch-type secondary battery is described as an example, but it may include secondary batteries of various shapes and structures such as a prismatic type, a cylindrical type, and a coin type.

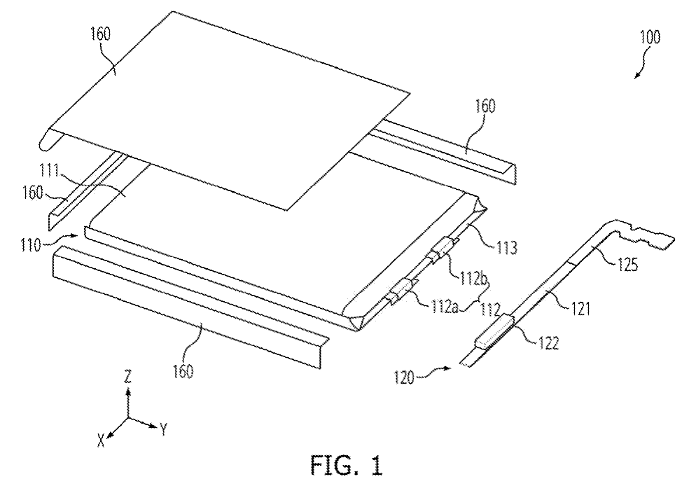

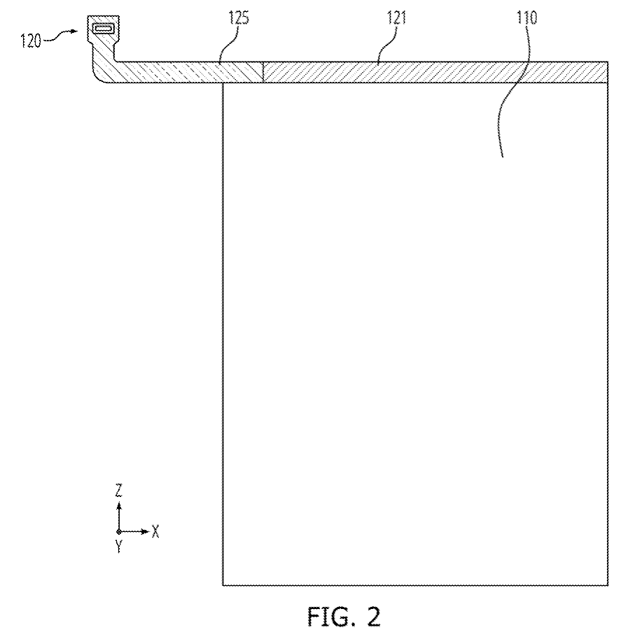

FIG. 1 is an exploded perspective view illustrating a battery assembly 100 according to an embodiment of the present disclosure. FIG. 2 is a plan view illustrating a battery assembly 100 according to an embodiment of the present disclosure.

Referring to FIG. 1, a battery assembly 100 may include a battery cell 110, a protection circuit module 120 electrically connected to the battery cell 110, a fixing tape fixing the protection circuit module 120 to the battery cell 110, and a cover tape 160 covering a surface of the battery cell 110.

A battery cell 110 may include an electrode assembly and a pouch exterior material 111 covering a surface of the electrode assembly. The electrode assembly may include a positive electrode plate, a negative electrode plate, and a separator interposed between the positive electrode plate and the negative electrode plate. An electrode tab 112 may protrude from one side of the electrode assembly. For example, a positive electrode tab 112a connected to the positive electrode plate may protrude, and a negative electrode tab 112b connected to the negative electrode plate may protrude. The pouch exterior material 111 may wrap around a surface of the electrode assembly such that the electrode tab 112 is exposed to the outside.

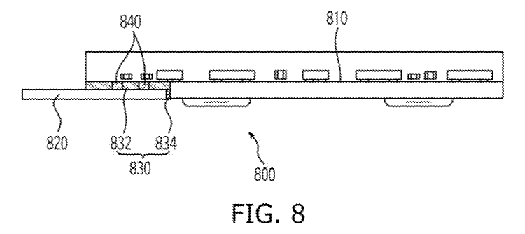

A protection circuit module 120 may perform a role of preventing overcharge, overdischarge, and/or overcurrent of a battery cell 110. The protection circuit module 120 may include a protection circuit board 121, a flexible circuit board 125, and an insulating resin. The insulating resin is between the protection circuit board 121 and the flexible circuit board 125, which will be described later in FIG. 8.

An electronic component 122 for monitoring and protecting a state of a battery cell 110 may be mounted on a protection circuit board 121. For example, electronic components 122 such as a relay, a capacitor, and a PTC (Positive Temperature Coefficient) thermistor may be mounted on the protection circuit board 121.

A protection circuit board 121 may be electrically connected to a battery cell 110. For example, the protection circuit board 121 may be electrically connected to an electrode tab 112 protruding from one side of the battery cell 110 through an electrode terminal. In this case, the electrode terminal connected to the positive electrode tab 112a may function as a positive electrode terminal, and the electrode terminal connected to the negative electrode tab 112b may function as a negative electrode terminal.

A flexible circuit board 125 may be connected to a protection circuit board 121. For example, the flexible circuit board 125 may be disposed on another surface of the protection circuit board 121, facing one surface of the protection circuit board 121 on which the electronic component 122 is mounted. The flexible circuit board 125 may be electrically connected to the protection circuit board 121 through a method such as soldering and other techniques.

In an embodiment, the flexible circuit board 125 may be a separable circuit board. For example, the flexible circuit board 125 is manufactured separately from the protection circuit board 121, and then may be connected to the protection circuit board 121 in the assembly step of the protection circuit module 120. Accordingly, various designs of the protection circuit board 121 may be possible. For example, the protection circuit board 121 may be applied to various types of battery assemblies 100 by changing only the design of the flexible circuit board 125 according to the type of the battery assembly 100 and connecting it to the protection circuit board 121.

In an embodiment, a flexible circuit board 125 may correspond to a FPCB (Flexible Printed Circuit Board). In this case, the flexible circuit board 125 may be designed in various forms, so that a degree of freedom in design may be high compared to a circuit board composed of a rigid material.

A flexible circuit board 125 may include an extension portion. The extension portion may refer to a portion protruding from one end of a protection circuit board 121 based on a length direction (e.g., X-axis direction) of the protection circuit board 121. A connector for connection to an external device may be connected to an end of the extension portion.

A protection circuit module 120 connected to a battery cell 110 may be seated on one side of the battery cell 110. A terrace portion 113 may be on one side (e.g., a direction in which the electrode tab 112 protrudes) of a pouch exterior material 111, and the terrace portion 113 may provide a space for the protection circuit module 120 to be seated. For example, an insulating tape may be disposed on the terrace portion 113, and the protection circuit module 120 may be seated on the insulating tape.

Referring to FIG. 2, a battery assembly may include a battery cell and a protection circuit module 120. A battery cell may include a pouch exterior material 111 covering an outside of the battery cell. The pouch exterior material 111 may include a terrace portion protruding in a direction in which an electrode tab of the battery cell protrudes. The protection circuit module 120 may be seated on the terrace portion of the pouch exterior material 111.

A protection circuit module 120 may include a protection circuit board 121 and a flexible circuit board 125. The protection circuit board 121 and the flexible circuit board 125 may extend in a first direction (e.g., an X-axis direction). At least a portion of the protection circuit board 121 may overlap with the flexible circuit board 125 in a second direction (e.g., a Z-axis direction) perpendicular to the first direction. For example, the protection circuit board 121 and the flexible circuit board 125 may be connected by soldering or blazing.

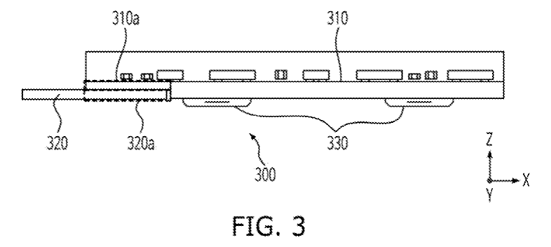

FIG. 3 illustrates a protection circuit module 300 according to an embodiment of the present disclosure. The protection circuit module 300 in FIG. 3 is an example of the protection circuit module 120 in FIGS. 1 and 2. For example, the protection circuit module 300 may correspond to the protection circuit module 120 shown in FIGS. 1 and 2 viewed in a Y-axis direction.

A protection circuit module 300 may include a protection circuit board 310, a flexible circuit board 320, and a tab connection portion 330. Although a shape of an electronic component is shown on the protection circuit board 310, this may vary.

A protection circuit board 310 is electrically connected to a battery cell and may extend in a first direction (e.g., an X-axis direction). The protection circuit board 310 may include a first binding portion 310a that overlaps with a flexible circuit board 320 in a second direction (e.g., a Z-axis direction) perpendicular to the first direction. According to an embodiment, the first binding portion 310a may be located at one end of the protection circuit board 310.

A flexible circuit board 320 includes a second binding portion 320a that overlaps with a protection circuit board 310 in a second direction (e.g., Z-axis direction) perpendicular to a first direction. The second binding portion 320a of the flexible circuit board 320 may be coupled to the protection circuit board 310. The second binding portion 320a may be located at one end of the flexible circuit board 320. The flexible circuit board 320 may be electrically connected to the protection circuit board 310. The first binding portion 310a of the protection circuit board 310 may be coupled to the flexible circuit board 320. For example, the first binding portion 310a and the second binding portion 320a may be coupled.

According to an embodiment, a thickness (e.g., in the Z-axis direction) of a first binding portion 310a may be less than a thickness of an area other than the first binding portion 310a in a protection circuit board 310. A thickness (e.g., in the X-axis direction) of a second binding portion 320a may be less than a thickness of an area other than the second binding portion 320a in a flexible circuit board 320. By reducing the thickness of the first binding portion 310a and the second binding portion 320a, the first binding portion 310a and the second binding portion 320a may be coupled in a block form. As a result, a total thickness of a protection circuit module 300 in which the protection circuit board 310 and the flexible circuit board 320 are coupled may be reduced. This configuration may reduce a thickness of a battery assembly. For example, a fastening thickness between the protection circuit board 310 and the flexible circuit board 320 may be reduced.

An electronic component may be mounted on one surface of a protection circuit board 310. According to an embodiment, the electronic component described above may include a protection IC, FET, resistors, capacitors, thermistors, diodes, electrostatic discharge devices (e.g., TVS diodes), and voltage regulators, or a combination thereof, that detect and block overvoltage, overcurrent, and overheating of a battery cell. However, the electronic component may include various electronic components for detecting abnormal states of a battery or storing and/or processing state information. For example, the electronic component may include an EEPROM or a microcontroller unit (MCU) for storing and/or processing battery cell state information. A predetermined space may be formed between electronic components, between an electronic component and the protection circuit board 310, and above an electronic component. According to an embodiment, a filling resin may be applied to the predetermined space and cured to prevent external impact or moisture penetration, and to improve mechanical stability of the electronic component and durability of the protection circuit module 300. For example, the filling resin described above may include epoxy resin, urethane resin, silicone resin, acrylic resin, or a combination thereof.

A tab connection portion 330 may be disposed on another surface of a protection circuit board 310, facing one surface of the protection circuit board 310 on which an electronic component is mounted. The tab connection portion 330 is connected to an electrode tab of a battery cell and may be electrically connected to an electrode assembly connected to the electrode tab. The tab connection portion 330 may be a conductor through which current for electrical connection may flow. For example, the tab connection portion 330 may be made of nickel. The connection between the tab connection portion 330 and the electrode tab may be made by soldering, resistance welding, laser welding, or projection welding.

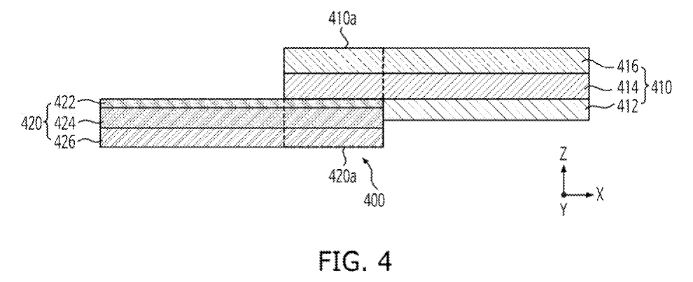

FIG. 4 illustrates an example in which a protection circuit board 410 and a flexible circuit board 420 are coupled according to an embodiment of the present disclosure. Referring to FIG. 4, a protection circuit module 400 in FIG. 4 is an example of the protection circuit module 120 in FIGS. 1 and 2. The protection circuit module 400 may include a protection circuit board 410 and a flexible circuit board 420.

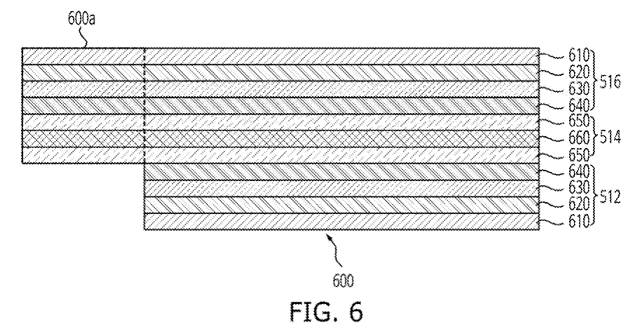

A protection circuit board 410 may include a first protective layer 412, a base layer 414, and a second protective layer 416 that are sequentially stacked in a second direction (e.g., a Z-axis direction). The first protective layer 412, the base layer 414, and the second protective layer 416 may each include at least one layer, and will be described in detail later in FIG. 6.

A protection circuit board 410 may include a first binding portion 410a which is an area overlapping with a flexible circuit board 420 in a second direction. A thickness of the first binding portion 410a may be less than a thickness of an area other than the first binding portion 410a. For example, at least a portion of a first protective layer 412 may be removed in the first binding portion 410a. According to an embodiment, the first protective layer 412 may be removed in the first binding portion 410a, and the first binding portion 410a may include only a base layer 414 and a second protective layer 416. According to another embodiment, a portion of the first protective layer 412 may be removed in the first binding portion 410a, and the first binding portion 410a may include the base layer 414, the second protective layer 416, and a portion of the first protective layer 412.

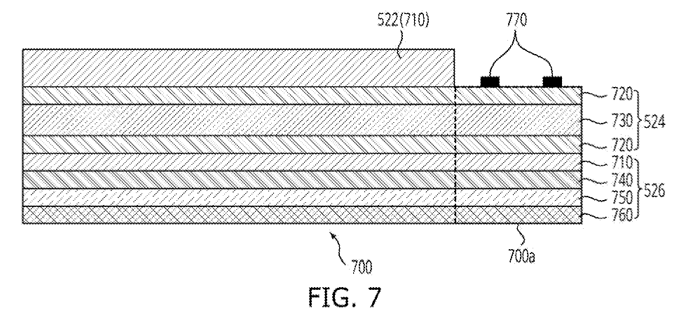

A flexible circuit board 420 may include a first flexible protective layer 422, a flexible base layer 424, and a second flexible protective layer 426 that are sequentially stacked in a second direction. The first flexible protective layer 422, the flexible base layer 424, and the second flexible protective layer 426 may each include at least one layer, and will be described in detail later in FIG. 7.

According to an embodiment, a first protective layer 412 is removed in a first binding portion 410a, and a base layer 414 may be exposed to the outside. One surface of the exposed base layer 414 of the first binding portion 410a may face one surface of a first flexible protective layer 422 of a second binding portion 420a corresponding thereto. One surface of the base layer 414 and one surface of the first flexible protective layer 422 may be electrically connected.

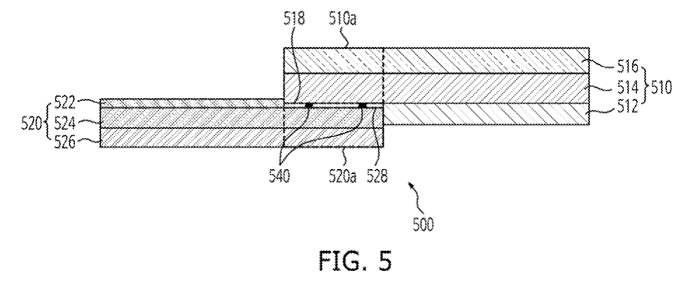

FIG. 5 illustrates an example in which a protection circuit board 510 and a flexible circuit board 520 are coupled according to an embodiment of the present disclosure.

Referring to FIG. 5, a protection circuit module 500 in FIG. 5 is an example of the protection circuit module 120 in FIGS. 1 and 2. The protection circuit module 500 may include a protection circuit board 510 and a flexible circuit board 520.

A protection circuit board 510 may include a first protective layer 512, a base layer 514, and a second protective layer 516 that are sequentially stacked in a second direction. The first protective layer 512, the base layer 514, and the second protective layer 516 may each include at least one layer, and will be described in detail later in FIG. 6.

A protection circuit board 510 may include a first binding portion 510a which is an area overlapping with a flexible circuit board 520 in a second direction. A configuration of the first binding portion 510a may correspond to the configuration described in FIG. 4, and redundant descriptions related to the first binding portion 510a are omitted.

A flexible circuit board 520 may include a first flexible protective layer 522, a flexible base layer 524, and a second flexible protective layer 526 that are sequentially stacked in a direction opposite to a second direction. The first flexible protective layer 522, the flexible base layer 524, and the second flexible protective layer 526 may each include at least one layer, and will be described in detail later in FIG. 7.

A flexible circuit board 520 includes a second binding portion 520a which is an area overlapping with a protection circuit board 510 in a second direction. A thickness of the second binding portion 520a may be less than a thickness of an area other than the second binding portion 520a. For example, a first flexible protective layer 522 may be removed in the second binding portion 520a. According to an embodiment, the first flexible protective layer 522 is removed in the second binding portion 520a, and the second binding portion 520a may include only a flexible base layer 524 and a second flexible protective layer 526. According to another embodiment, a portion of the first flexible protective layer 522 may be removed in the second binding portion 520a. The second binding portion 520a may include the flexible base layer 524, the second flexible protective layer 526, and a portion of the first flexible protective layer 522.

According to an embodiment, a first protective layer 512 is removed in a first binding portion 510a, so a base layer 514 may be exposed to the outside, and a first flexible protective layer 522 is removed in a second binding portion 520a, so a flexible base layer 524 may be exposed to the outside. One surface of the exposed base layer 514 may face one surface of the flexible base layer 524 corresponding thereto. One surface of the base layer 514 and one surface of the flexible base layer 524 may be electrically connected.

According to an embodiment, a first protective layer may be only in a portion of a lower surface of a protection circuit board. For example, a first stepped surface 518 may be on the lower surface of the protection circuit board due to a height difference between an area where the first protective layer is formed and an area where the first protective layer is not formed. A first flexible protective layer may be only in some regions of an upper surface of a flexible base layer of a flexible circuit board. For example, a second stepped surface 528 may be formed due to a height difference between a region where the first flexible protective layer is formed and a region where the first flexible protective layer is not formed. The second stepped surface 528 may be arranged to correspond to the first stepped surface 518, through which the protection circuit board and the flexible circuit board are aligned along a second direction, enhancing the structural coupling stability between the two boards.

According to an embodiment, a connection member 540 is on a second binding portion 520a and may electrically connect a flexible circuit board 520 to a protection circuit board 510. For example, the connection member 540 may be between a second copper layer of a base layer and a first copper layer of a flexible base layer. For example, the connection member 540 is on an upper surface of a copper layer included in a flexible base layer 524 of the flexible circuit board 520, and may be disposed to overlap with a first binding portion 510a of the protection circuit board 510 along a second direction. For example, the first binding portion 510a is an area where a first protective layer 512 of the protection circuit board 510 is removed, and may have a structure in which a second copper layer of a base layer 514 is exposed to the outside. Accordingly, the connection member 540 is located between the copper layer of the flexible circuit board 520 and the copper layer of the protection circuit board 510, and may be formed in a conductive bonding structure that electrically connects the two conductive layers described above.

In an embodiment, a flexible circuit board 520 may include a connection member 540, and the connection member 540 may be formed in advance on a surface of a second binding portion 520a before the flexible circuit board 520 is coupled to a protection circuit board 510. For example, the connection member 540 may be formed by applying solder paste onto a copper layer of a flexible base layer 524, and then undergoing a reflow method or a thermal compression bonding process after alignment and stacking processes with the protection circuit board 510. For example, the connection member 540 is a conductive member formed in a local area and may contribute to forming a current path such as a signal line or a power line between the protection circuit board 510 and the flexible circuit board 520. The connection member 540 may be formed through soldering. The connection member 540 will be described later in FIG. 8.

FIG. 6 illustrates an example of a stacked structure constituting a protection circuit board 600 according to an embodiment of the present disclosure.

A protection circuit board 600 is an example of the protection circuit board 510 in FIG. 5. The protection circuit board 600 may include a first protective layer 512, a base layer 514, and a second protective layer 516 that are sequentially stacked in a second direction. The first protective layer 512, the base layer 514, and the second protective layer 516 may each include at least one layer, and will be described below.

A first protective layer 512 may include a first insulating layer 610, a first copper layer 620, a second copper layer 630, and a second insulating layer 640. The first insulating layer 610, the first copper layer 620, the second copper layer 630, and the second insulating layer 640 may be sequentially stacked in a second direction. For example, the first insulating layer 610 may be disposed at a lowermost portion of the first protective layer 512, and the second insulating layer 640 may be disposed at an uppermost portion of the first protective layer 512. The first insulating layer 610 may perform a function of distinguishing a soldering area from an insulating area. The first copper layer 620 and the second copper layer 630 may function as signal movement paths. The second insulating layer 640 may perform a role of adhesion and insulation between upper and lower layers.

A first copper layer 620 may be a plated copper layer formed by an electroplating method on a surface after circuit formation. According to an embodiment, the first copper layer 620 may be formed by an electroplating method on a second copper layer 630 below for purposes such as improving conductivity, securing surface flatness, and improving solderability after circuit formation. The first copper layer 620 may be selectively formed in a connection pad area or a wiring pattern area as needed, and may function as a surface conductor for electrical connection with an external circuit. The first copper layer 620 may contribute to improving interfacial adhesion properties with a solder resist pattern or a surface treatment layer in a subsequent process.

A second copper layer 630 may be a copper layer for circuit formation disposed adjacent to an insulating layer. In an embodiment, the second copper layer 630 is included in a protective layer of a protection circuit board 600, and may be a copper material layer stacked for forming a conductive circuit pattern. A wiring pattern may be on the second copper layer 630 through photolithography and chemical etching processes, and the second copper layer 630 may function as an internal signal line or a connection pad. The second copper layer 630 secures adhesion stability at an interface with upper and lower insulating layers, and may contribute to improving electrical characteristics and mechanical durability of an entire circuit board.

A first insulating layer 610 and a second insulating layer 640 may each include a photosensitive insulating layer or an adhesive insulating layer. In an embodiment, the photosensitive insulating layer may include an insulating material having photosensitive properties. For example, a predetermined pattern may be on the photosensitive insulating layer through exposure and development processes, and a wiring formation area and a non-contact area on the photosensitive insulating layer may be selectively distinguished. In an embodiment, the adhesive insulating layer may be a structure in which a separate adhesive material is applied to a surface of an insulating layer. For example, the adhesive insulating layer may be formed in a form in which an acrylic or epoxy adhesive is applied to a film of a polyimide (PI) or polyester (PET) type. In other embodiments, the adhesive insulating layer may be composed of a thermosetting or thermoplastic insulating material in which the insulating layer itself has adhesive properties. The insulating layer described above may include a single layer or a stacked structure composed of at least one layer depending on required pattern formation precision, adhesion strength, insulating properties, and the like.

A second protective layer 516 may include a first insulating layer 610, a first copper layer 620, a second copper layer 630, and a second insulating layer 640. The first insulating layer 610, the first copper layer 620, the second copper layer 630, and the second insulating layer 640 may be sequentially stacked in a second direction. For example, the second insulating layer 640 may be disposed at a lowermost portion of the second protective layer 516, and the first insulating layer 610 may be disposed at an uppermost portion of the second protective layer 516. A function of each layer may be the same as the function of the first insulating layer 610, the first copper layer 620, the second copper layer 630, and the second insulating layer 640 of the first protective layer 512 described above.

A base layer 514 may include a plurality of second copper layers 650 and an insulating layer 660 between the plurality of second copper layers 650. The plurality of second copper layers 650 and the insulating layer 660 between the plurality of second copper layers 650 may be sequentially stacked in a second direction. For example, the second copper layer 650 may be disposed at a lowermost portion and an uppermost portion of the base layer 514. The insulating layer 660 between the plurality of second copper layers 650 may function as a signal transmission path.

A base layer 514 may be located between a second insulating layer 640 of a first protective layer 512 and a second insulating layer 640 of a second protective layer 516. For example, a plurality of second copper layers 650 of the base layer 514 may be between the second insulating layer 640 of the first protective layer 512 and the second insulating layer 640 of the second protective layer 516.

A protection circuit board 600 may include a first binding portion 600a which is an area overlapping with a flexible circuit board in a second direction. At least a portion of a first protective layer 512 may be removed in the first binding portion 600a. For example, a first insulating layer 610, a first copper layer 620, a second copper layer 630, and a second insulating layer 640 may be removed. According to an embodiment, the first protective layer 512 is removed in the first binding portion 600a, and the first binding portion 600a may include only a base layer 514 and a second protective layer 516. Therefore, a second copper layer 650 of the base layer 514 may be exposed to the outside in the first binding portion 600a. The second copper layer 650 of the base layer 514 may be directly exposed to the outside and may be used as a conductive layer through soldering or similar process.

As described with respect to FIG. 4, a flexible circuit board may include a first flexible protective layer, a flexible base layer, and a second flexible protective layer that are sequentially stacked in a second direction. According to an embodiment, one surface of the exposed second copper layer 650 of the base layer 514 may face one surface of the first flexible protective layer corresponding thereto. For example, one surface of the second copper layer 650 of the base layer 514 and one surface of the first flexible protective layer may be electrically connected.

FIG. 7 illustrates an example of layers constituting a flexible circuit board 700 according to an embodiment of the present disclosure.

Referring to FIG. 7, a flexible circuit board 700 in FIG. 7 is an example of the flexible circuit board 520 in FIG. 5. The flexible circuit board 700 may include a first flexible protective layer 522, a flexible base layer 524, and a second flexible protective layer 526 that are sequentially stacked in a second direction. The first flexible protective layer 522, the flexible base layer 524, and the second flexible protective layer 526 may each include at least one layer.

A first flexible protective layer 522 may include a coverlay layer 710. The coverlay layer 710 may block a first copper layer 720 from being connected to an external component, thereby preventing current leakage, and may protect a flexible circuit board 700 from the outside. The coverlay layer 710 may be stacked on a topmost portion of the flexible circuit board 700 in a second direction.

A second flexible protective layer 526 may include a coverlay layer 710, a bond sheet layer 740, an epoxy layer 750, and a surface treatment layer 760. The coverlay layer 710, the bond sheet layer 740, the epoxy layer 750, and the surface treatment layer 760 may be sequentially stacked in a second direction. For example, the surface treatment layer 760 may be disposed at a lowermost portion of the second flexible protective layer 526, and the coverlay layer 710 may be disposed at an uppermost portion of the second flexible protective layer 526. The coverlay layer 710 may perform the same role as described above in the first flexible protective layer 522.

In an embodiment, a coverlay layer 710, a bond sheet layer 740, an epoxy layer 750, and a surface treatment layer 760 may each be formed as a single layer, or may be formed as a stacked structure in which at least one layer is sequentially stacked. For example, each layer may be implemented as a stacked structure in which a plurality of layers having different physical properties are sequentially stacked to secure mechanical rigidity, improve thermal reliability, or reinforce electrical insulation properties. According to such a configuration, the second flexible protective layer 526 may be designed in various stacking combinations according to required use environments or performance conditions, and may improve physical durability and electrical stability of the flexible circuit board 700.

A flexible base layer 524 may include a plurality of first copper layers 720 and a flexible copper clad laminate 730 between the plurality of first copper layers 720. For example, the first copper layer 720 may be disposed at a lowermost portion and an uppermost portion of the flexible base layer 524. The flexible copper clad laminate 730 between the plurality of first copper layers 720 may function as a signal transmission path. The flexible copper clad laminate 730 may include a second copper layer and an insulating layer that are sequentially stacked.

A flexible base layer 524 may be located between a coverlay layer 710 of a first flexible protective layer 522 and a coverlay layer 710 of a second flexible protective layer 526. For example, a plurality of first copper layers 720 of the flexible base layer 524 may be between the coverlay layer 710 of the first flexible protective layer 522 and the coverlay layer 710 of the second flexible protective layer 526.

A flexible circuit board includes a second binding portion 700a which is an area overlapping with a protection circuit board in a second direction. At least a portion of a first flexible protective layer 522 may be removed in the second binding portion 700a. For example, a coverlay layer 710 may be removed. According to an embodiment, the first flexible protective layer 522 is removed in the second binding portion 700a, and the second binding portion 700a may include only a flexible base layer 524 and a second flexible protective layer 526. Therefore, a first copper layer 720 of the flexible base layer 524 may be exposed to the outside in the second binding portion 700a. The first copper layer 720 of the flexible base layer 524 may be directly exposed to the outside and may be used as a conductive layer through soldering or similar processes.

As described with respect to FIG. 5, a protection circuit board may include a first protective layer, a base layer, and a second protective layer that are sequentially stacked in a second direction. According to an embodiment, one surface of the exposed first copper layer 720 of the flexible base layer 524 may face one surface of the second copper layer of the base layer corresponding thereto. One surface of the second copper layer of the flexible base layer and one surface of the first copper layer 720 of the flexible base layer 524 may be electrically connected.

A flexible circuit board 700 may include at least one connection member 770 on a flexible base layer 524. The connection member 770 may electrically connect the flexible base layer 524 to the base layer. For example, a plurality of connection members 770 may be on a first copper layer 720 of the flexible base layer 524. The first copper layer 720 of the flexible base layer 524 and the second copper layer of the base layer may be electrically connected through the connection member 770.

FIG. 8 illustrates an exemplary insulating resin 830 and connection member 840 in a coupling structure between a protection circuit board 510 and a flexible circuit board 520 according to an embodiment of the present disclosure.

Referring to FIG. 8, a protection circuit module 800 in FIG. 8 is an example of the protection circuit module 120 in FIGS. 1 and 2. The protection circuit module 800 may include a protection circuit board 810, a flexible circuit board 820, an insulating resin 830 between the protection circuit board 810 and the flexible circuit board 820, and a connection member 840.

An insulating resin 830 may include a first insulating portion 832 between a protection circuit board 810 and a flexible circuit board 820 in a second direction, and a second insulating portion 834 between the protection circuit board 810 and the flexible circuit board 820 in a first direction. For example, the first insulating portion 832 may be between a second copper layer of a base layer and a first copper layer of a flexible base layer. The second insulating portion 834 may be connected to the first insulating portion 832 in a vertical direction.

A connection member 840 is on a second binding portion of a flexible circuit board 820 and may electrically connect the flexible circuit board 820 to a protection circuit board 810. For example, the connection member 840 may be between a second copper layer of a base layer and a first copper layer of a flexible base layer. The connection member 840 may be formed through soldering. Stress due to current in a base layer may be adjusted by adjusting a number of connection members 840.

For example, the first insulating portion 832 may fill a space between a first binding portion and a second binding portion, except for an area where a connection member 840 is formed. Through this configuration, a protection circuit board 810 and a flexible circuit board 820 may be insulated from each other, inflow of foreign substances and short circuits may be prevented, and binding force of the protection circuit board 810 and the flexible circuit board 820 may be increased.

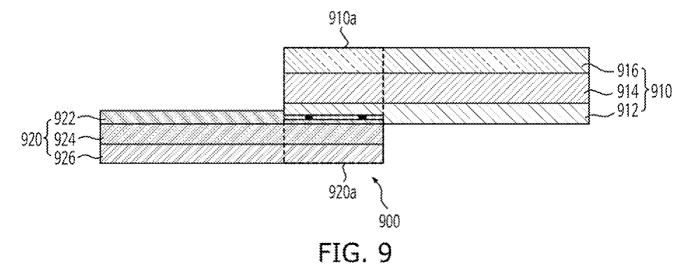

FIG. 9 illustrates an example in which a protection circuit board 910 and a flexible circuit board 920 are coupled according to an embodiment of the present disclosure. Referring to FIG. 9, a protection circuit module 900 in FIG. 9 is an example of the protection circuit module 120 in FIGS. 1 and 2. The protection circuit module 900 may include a protection circuit board 910 and a flexible circuit board 920.

A protection circuit board 910 includes a first protective layer 912, a base layer 914, and a second protective layer 916 that are sequentially stacked in a second direction, and a flexible circuit board 920 may include a first flexible protective layer 922, a flexible base layer 924, and a second flexible protective layer 926 that are sequentially stacked in a second direction. Detailed configurations of each layer are the same in FIGS. 6 and 7.

A portion of a first protective layer 912 may be removed in a first binding portion 910a. For example, a first insulating layer of the first protective layer 912 is removed, and a first copper layer of the first protective layer 912 may be exposed. The first copper layer may be directly exposed to the outside and used as a conductive layer through soldering. A first flexible protective layer 922 may be removed in a second binding portion 920a. For example, a coverlay layer of the second binding portion 920a may be removed.

According to an embodiment, a first copper layer of a first protective layer 912 and a first copper layer of a flexible base layer 924 may face each other. A connection member is between the first copper layer of the first protective layer 912 and the first copper layer of the flexible base layer 924, and the connection member may electrically connect the first copper layers to each other. An insulating resin may fill an empty space between a protection circuit board 910 and a flexible circuit board 920.

According to some embodiments of the present disclosure, a protection circuit board and a flexible circuit board are coupled in a block manner, and a total thickness of a protection circuit module may be reduced.

According to some embodiments of the present disclosure, a fastening thickness between a protection circuit board and a flexible circuit board may be reduced.

According to some embodiments of the present disclosure, stress due to current in a base layer may be adjusted by adjusting a number of connection members between a protection circuit board and a flexible circuit board.

According to some embodiments of the present disclosure, an insulating resin between a protection circuit board and a flexible circuit board may insulate the protection circuit board and the flexible circuit board from each other, thereby preventing the inflow of foreign substances and short circuits, and may increase the binding force between the protection circuit board and the flexible circuit board.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated.Accordingly, it will be understood by those of skill in the art that various changes in form and details may be made without departing from the spirit and scope of the present invention as set forth in the following claims.

What is claimed is:

1. A protection circuit module, comprising:
a protection circuit board extending in a first direction; and
a flexible circuit board electrically connected to the protection circuit board, wherein:
the protection circuit board comprises a first binding portion overlapping with the flexible circuit board in a second direction perpendicular to the first direction,
the first binding portion of the protection circuit board is coupled to the flexible circuit board, and
a thickness of the first binding portion is less than a thickness of an area other than the first binding portion in the protection circuit board.

2. The protection circuit module as claimed in claim 1, wherein the flexible circuit board comprises a second binding portion overlapping with the protection circuit board in a second direction perpendicular to the first direction.

3. The protection circuit module as claimed in claim 2, wherein:
the protection circuit board comprises a first protective layer, a base layer, and a second protective layer that are sequentially stacked, and
at least a portion of the first protective layer is removed in the first binding portion.

4. The protection circuit module as claimed in claim 3, wherein each of the first protective layer and the second protective layer comprises a first insulating layer, a first copper layer, a second copper layer, and a second insulating layer.

5. The protection circuit module as claimed in claim 3, wherein:
the flexible circuit board comprises a first flexible protective layer, a flexible base layer, and a second flexible protective layer that are sequentially stacked, and
at least a portion of the first flexible protective layer is removed in the second binding portion.

6. The protection circuit module as claimed in claim 5, wherein the first flexible protective layer comprises a coverlay layer.

7. The protection circuit module as claimed in claim 1, wherein the first binding portion is at one end of the protection circuit board.

8. The protection circuit module as claimed in claim 2, wherein the second binding portion is at one end of the flexible circuit board.

9. The protection circuit module as claimed in claim 2, further comprising an insulating resin between the protection circuit board and the flexible circuit board.

10. The protection circuit module as claimed in claim 9, wherein the insulating resin comprises:
a first insulating portion between the protection circuit board and the flexible circuit board in the second direction, and
a second insulating portion between the protection circuit board and the flexible circuit board in the first direction.

11. The protection circuit module as claimed in claim 5, wherein the flexible circuit board comprises at least one connection member on the second binding portion, the flexible circuit board being electrically connected to the protection circuit board.

12. The protection circuit module as claimed in claim 11, wherein the at least one connection member is connected to the flexible base layer of the second binding portion and the base layer of the first binding portion.

13. The protection circuit module as claimed in claim 5, wherein the base layer comprises:
a plurality of second copper layers and
an insulating layer between the plurality of second copper layers.

14. The protection circuit module as claimed in claim 13, wherein the flexible base layer comprises:
a plurality of first copper layers, and
a flexible copper clad laminate between the plurality of first copper layers.

15. The protection circuit module as claimed in claim 14, wherein the flexible circuit board comprises at least one connection member on the flexible base layer, the flexible circuit board being electrically connected to the flexible base layer and the base layer.

16. A protection circuit module, comprising:
a protection circuit board extending in a first direction;
a flexible circuit board overlapping with the protection circuit board in a second direction perpendicular to the first direction; and
a connection member between the protection circuit board and the flexible circuit board,
wherein the protection circuit board comprises:
a base layer;
a first protective layer on a lower surface of the base layer, the first protective layer not overlapping with the flexible circuit board in the second direction; and
a second protective layer on an upper surface of the base layer,
wherein the flexible circuit board comprises:
a flexible base layer;
a first flexible protective layer on an upper surface of the flexible base layer, the first flexible protective layer not overlapping with the protection circuit board in the second direction; and
a second flexible protective layer on a lower surface of the flexible base layer, and
wherein the connection member electrically connects the lower surface of the base layer with the upper surface of the flexible base layer.

17. The protection circuit module as claimed in claim 16, wherein:
a lower surface of the protection circuit board comprises a first stepped surface with the first protective layer, and
an upper surface of the flexible circuit board corresponds to the first stepped surface, the upper surface of the flexible circuit board comprising a second stepped surface with the first flexible protective layer.

18. The protection circuit module as claimed in claim 16, further comprising an insulating resin between the protection circuit board and the flexible circuit board, wherein the insulating resin comprises:
a first insulating portion between the base layer and the flexible base layer in the second direction, and
a second insulating portion between the first protective layer and the flexible circuit board in the first direction.

19. A battery assembly, comprising:
a battery cell comprising an electrode tab; and
a protection circuit module electrically connected to the electrode tab,
wherein the protection circuit module comprises:
a protection circuit board electrically connected to the battery cell, the protection circuit board extending in a first direction; and
a flexible circuit board electrically connected to the protection circuit board, wherein:
the protection circuit board comprises a first binding portion overlapping with the flexible circuit board in a second direction perpendicular to the first direction,
the first binding portion of the protection circuit board is coupled to the flexible circuit board, and
a thickness of the first binding portion is less than a thickness of an area other than the first binding portion in the protection circuit board.

20. The battery assembly as claimed in claim 19, wherein:
the flexible circuit board comprises a second binding portion overlapping with the protection circuit board in a second direction perpendicular to the first direction,
the second binding portion of the flexible circuit board is coupled to the protection circuit board, and
a thickness of the second binding portion is less than a thickness of an area other than the second binding portion in the flexible circuit board.
